(19) United States
(12) Patent Application Publication
(10) Pub. No.: US 2013/0002396 A1
(43) Pub. Date: Jan. 3, 2013

(54) COMMUNICATION DEVICE, COMMUNICATION CIRCUIT, AND METHOD

(75) Inventor: Mitsuru Sato, Machida (JP)

(73) Assignee: FUJITSU LIMITED, Kawasaki-shi (JP)

(21) Appl. No.: 13/532,919

(22) Filed: Jun. 26, 2012

(30) Foreign Application Priority Data
Jun. 29, 2011 (JP) 2011-143863

(51) Int. Cl. H03K 17/00

(52) U.S. Cl. 340/2.1

(57) ABSTRACT

A communication device includes a controller configured to determine whether a plurality of communication lines coupled to the communication device are available, assign logical communication line numbers to communication lines selected from the communication lines included in the transmission path, which are determined to be available in accordance with results of the determination in ascending order or descending order of the communication line numbers, and perform a process of establishing a link of the transmission path in accordance with the assigned logical communication line numbers.

### CROSS-REFERENCE TO RELATED APPLICATION(S)

This application is based upon and claims the benefit of priority of the prior Japanese Patent Application No. 2011-143863, filed on Jun. 29, 2011, the entire contents of which are incorporated herein by reference.

### FIELD

The embodiments discussed herein are related to a communication device, a communication circuit, and a communication method.

### BACKGROUND

In recent years, high-speed data transmission of information processing systems has been developed, and in addition, serial transmission has been widely used. Furthermore, for the high-speed data transmission, a multilane configuration in which serial transmission paths constituted by a plurality of lanes are collectively used as a single link has been used.

Furthermore, techniques associated with data transmission using a plurality of lanes has been known (refer to Japanese Laid-open Patent Publication Nos. 5-160819 and 2006-186527).

Here, it is assumed that, when a plurality of communication lines are used as a single transmission path such as the case where serial transmission paths are used as a multilane configuration, failures occur in a number of the communication lines among the plurality of communication lines, and therefore, the failed communication lines are not available. In this case, if a link is not established in all the serial transmission paths and the serial transmission paths become not available, availability of the transmission paths is degraded, which is a problem.

### SUMMARY

According to an aspect of the invention, a communication device includes a controller configured to determine whether the communication lines are available, assign logical communication line numbers to communication lines selected from the communication lines included in the transmission path, which are determined to be available in accordance with results of the determination in ascending order or descending order of the communication line numbers, and perform a process of establishing a link of the transmission path in accordance with the assigned logical communication line numbers.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating communication devices according to a first embodiment;

FIG. 2 is a diagram illustrating a configuration of a communication system according to a second embodiment;

FIG. 3 is a diagram illustrating a transmitter according to the second embodiment;

FIG. 4 is a diagram illustrating a receiver according to the second embodiment;

FIG. 5 is a diagram illustrating communication devices according to the second embodiment;

FIGS. 6A and 6B are diagrams illustrating a reconfiguration of lanes according to the second embodiment;

FIG. 7 is a flowchart illustrating a connection process according to the second embodiment;

FIG. 8 is a flowchart illustrating the connection process according to the second embodiment;

FIG. 9 is a flowchart illustrating a reconfiguration process according to the second embodiment;

FIG. 10 is a diagram illustrating communication devices according to a third embodiment;

FIG. 11 is a diagram illustrating a assigning table according to the third embodiment;

FIGS. 12A and 12B are diagrams illustrating a reconfiguration of lanes according to the third embodiment; and

FIG. 13 is a flowchart illustrating a reconfiguration process according to the third embodiment.

### DESCRIPTION OF EMBODIMENTS

Embodiments of the present disclosure will be described hereinafter with reference to the accompanying drawings.

### First Embodiment

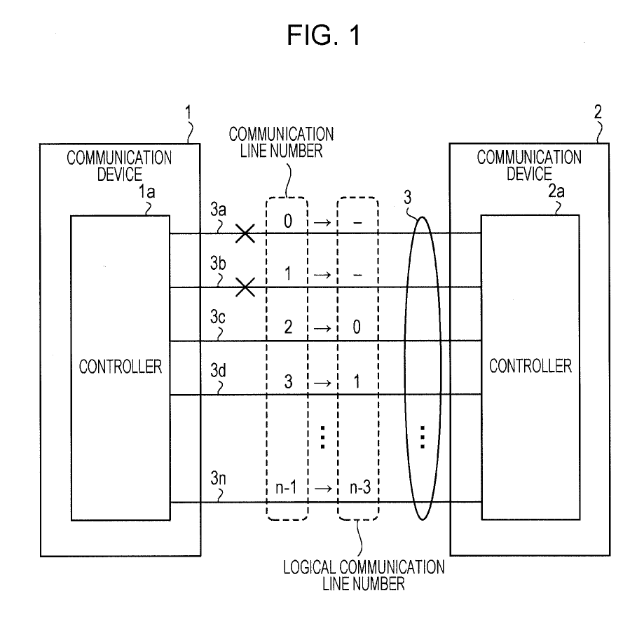

FIG. 1 is a diagram illustrating communication devices according to a first embodiment. Communication devices 1 and 2 illustrated in FIG. 1 which are connected to each other through a transmission path 3 communicate with each other through the transmission path 3 so as to transmit and receive data. The communication device 1 includes a controller 1a. The communication device 2 includes a controller 2a. The transmission path 3 includes n communication lines 3a to 3n. It is assumed that physical line numbers 0 to n−1 are assigned to the communication lines 3a to 3n. Furthermore, it is assumed that failures have occurred in the communication lines 3a and 3b, and therefore, the communication lines 3a and 3b are not available.

The controller 1a determines whether the communication lines 3a to 3n of the transmission path 3 are available. Here, it is assumed that the controller 1a determines that the failures have occurred in the communication lines 3a and 3b, and therefore, the communication lines 3a and 3b are not available but the communication lines 3c to 3n are available. Subsequently, the controller 1a assigns logical communication line numbers to the communication lines 3c to 3n in ascending order of the communication line numbers or descending order of the communication line numbers of the communication lines 3c to 3n which are determined to be available (in this case, starting from the communication line 3c). Specifically, the controller 1a ignores the communication lines 3a and 3b which are not available and assigns 0 serving as a logical line number to the communication line 3c which is available and which has the smallest communication line number 2. Furthermore, the controller 1a assigns 1 serving as a logical line number to the communication line 3d which is available and which has a communication line number 3, and similarly, assigns n−3 serving as a logical line number to the communication line 3n which is available and which has a communication line number n−1.

Then the controller 1a executes a process of establishing a link of the transmission path 3 in accordance with the assigned logical communication line numbers. In this way, the communication devices 1 and 2 communicate with each other through the transmission path 3 so as to transmit and receive data.

The controller 2a has the same configuration as the controller 1a, and therefore, a description thereof is omitted.

Accordingly, when a number of communication lines among the plurality of communication lines included in the transmission path 3 which is used to connect the communication devices 1 and 2 to each other are not available, the communication using the link of the transmission path 3 established by the available communication lines can be continued.

Note that each of the communication devices of the first embodiment may be implemented as a communication device including a communication interface of the PCI (Peripheral Component Interconnect) Express. In second and third embodiments described below, communication devices based on the PCI Express will be described as examples. Note that each of the communication devices of the first embodiment may be implemented as a communication device including a certain communication interface such as the InfiniBand (trademark). Furthermore, each of the communication devices of the first embodiment may be realized as an information processing apparatus including a certain communication interface such as the PCI Express or the InfiniBand.

### Second Embodiment

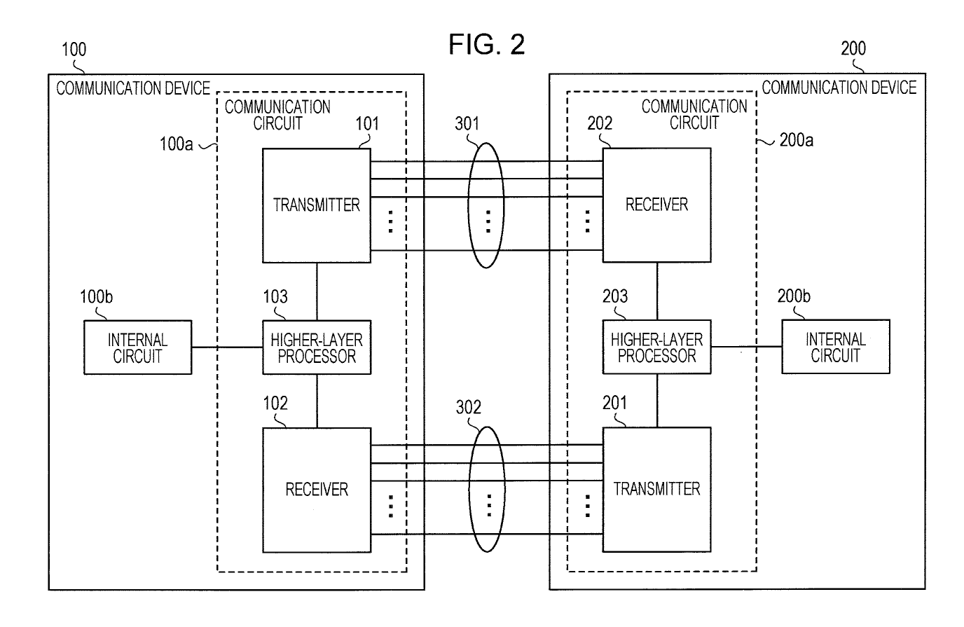

FIG. 2 is a diagram illustrating a configuration of a communication system according to the second embodiment. In the communication system of the second embodiment, communication devices 100 and 200 are connectable to each other using serial links 301 and 302 each of which includes n synchronized lanes (16 lanes, for example). In the second embodiment, a transmitter 101 included in the communication device 100 and a receiver 202 included in the communication device 200 are connected to each other through the serial link 301. Furthermore, a receiver 102 included in the communication device 100 and a transmitter 201 included in the communication device 200 are connected to each other through the serial link 302.

The communication device 100 includes a communication circuit 100a and an internal circuit 100b. The communication circuit 100a includes the transmitter 101, the receiver 102, and a higher-layer processor 103.

The transmitter 101 performs control of physical connection of the serial link 301 disposed between the transmitter 101 and the receiver 202 of the communication device 200 and a transmission process such as a transmission of an optical signal to the receiver 202 in the physical layer of the OSI (Open System Interconnection) reference model. Note that the transmitter 101 may perform a process of transmitting an electric signal instead of the process of transmitting an optical signal.

The receiver 102 performs control of physical connection of the serial link 302 disposed between the receiver 102 and the transmitter 201 of the communication device 200 and a reception process such as a reception of an optical signal supplied from the transmitter 201 in the physical layer. Note that the receiver 102 may perform a process of receiving an electric signal instead of the process of receiving an optical signal.

The higher-layer processor 103 performs a transmission/reception process in layers higher than the data link layer of the OSI reference model. Furthermore, the higher-layer processor 103 controls communication performed by the transmitter 101 and the receiver 102. When receiving transmission data from the internal circuit 100b, the higher-layer processor 103 causes the transmitter 101 to transmit the transmission data to the receiver 202. Furthermore, when receiving reception data which is supplied from the transmitter 201 and received by the receiver 102, the higher-layer processor 103 transmits the reception data to the internal circuit 100b.

The internal circuit 100b enables data communication with the communication device 200 and processes transmission data and reception data. The internal circuit 100b may be realized by dedicated hardware, a microprocessor, a memory, or software.

The lanes included in the serial links 301 and 302 are used to transmit data as optical signals, for example. However, the lanes may be used to transmit data by communication of electric signals. A data transmission speed of each of the lanes is 4 Gbps (Giga bits per second), for example. When the serial link 301 has 16 lanes, a data transmission speed of the serial link 301 is 64 Gbps. The number of lanes included in each of the serial links 301 and 302 may be 4, 8, or the like.

Note that, the communication device 200 includes a communication circuit 200a including the transmitter 201, the receiver 202, and a higher-layer processor 203 and an internal circuit 200b. The communication device 200 has the same configuration as the communication device 100, and therefore, a description thereof is omitted.

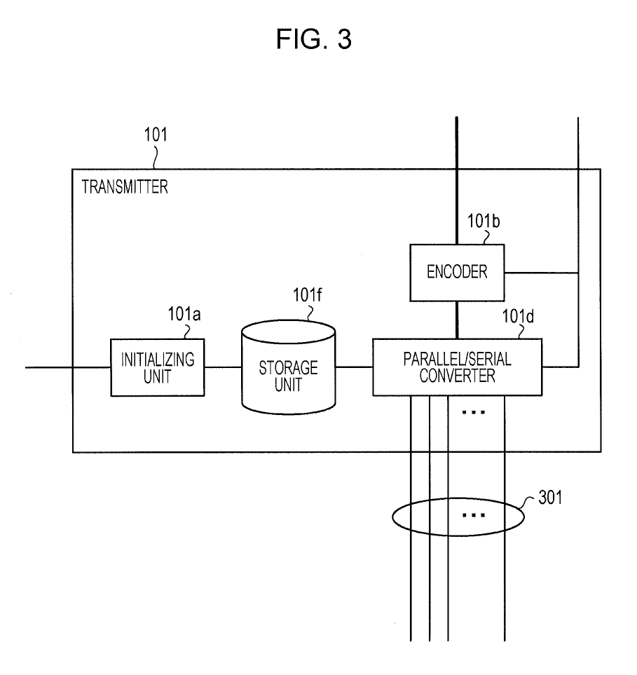

FIG. 3 is a diagram illustrating the transmitter 101 according to the second embodiment. The transmitter 101 includes an initializing unit 101a, an encoder 101b, a parallel/serial converter 101d, and a storage unit 101f.

The initializing unit 101a performs an initializing process before the link of the serial link 301 which is connected to the receiver 202 of the communication device 200 is established so as to determine the number of lanes used for communication and lane mapping. Information on the number of lanes used for communication and information on the lane mapping are stored in the storage unit 101f.

The encoder 101b performs an encoding process such that transmission data transmitted from the transmitter 101 of the communication device 100 to the communication device 200 is converted into a physical transmission bit string in accordance with a transmission clock generated by a clock generator, not illustrated.

The parallel/serial converter 101d performs a process of converting a parallel signal of the data encoded by the encoder 101b into a serial signal in accordance with the transmission clock generated by the clock generator, not illustrated.

The storage unit 101f stores the information on the number of lanes used for communication and the information on the lane mapping which are determined by the initializing unit 101a. Furthermore, the storage unit 101f stores assigning information representing the correspondence relationships between physical lane numbers used to identify the lanes and logical lane numbers assigned to available lanes.

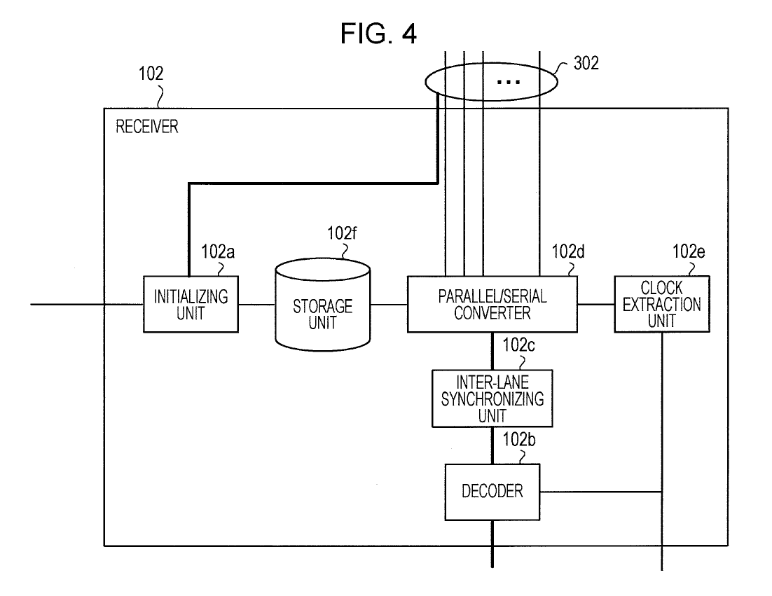

FIG. 4 is a diagram illustrating the receiver 102 according to the second embodiment. The receiver 102 includes an initializing unit 102a, a decoder 102b, an inter-lane synchronizing unit 102c, a parallel/serial converter 102d, a clock extraction unit 102e, and a storage unit 102f.

The initializing unit 102a performs an initializing process before the link of the serial link 302 which is connected to the receiver 201 of the communication device 200 is established so as to determine the number of lanes used for communication and lane mapping. Information on the number of lanes used for communication and information on the lane mapping are stored in the storage unit 102f.

The decoder 102b performs a decoding process such that a physical transmission bit string of reception data which is transmitted from the communication device 200 to the communication device 100 and received by the receiver 102 is converted into data in accordance with a reception clock or the like extracted by the clock extraction unit 102e.

The inter-lane synchronizing unit 102c performs a process of extracting synchronization signals included in transmission bits of the lanes included in the serial link 302 which are converted into parallel signals by the parallel/serial converter 102d and synchronizing the data of the lanes.

The parallel/serial converter 102d performs a process of converting a serial signal supplied from the communication device 200 into a parallel signal in accordance with the reception clock or the like extracted by the clock extraction unit 102e.

The clock extraction unit 102e extracts the reception clock from a data signal supplied from the communication device 200.

The storage unit 102f stores the information on the number of lanes used for communication and the information on the lane mapping which are determined by the initializing unit 102a. Furthermore, the storage unit 102f stores assigning information representing the correspondence relationships between the physical lane numbers and logical lane numbers which are separately assigned to the available lanes.

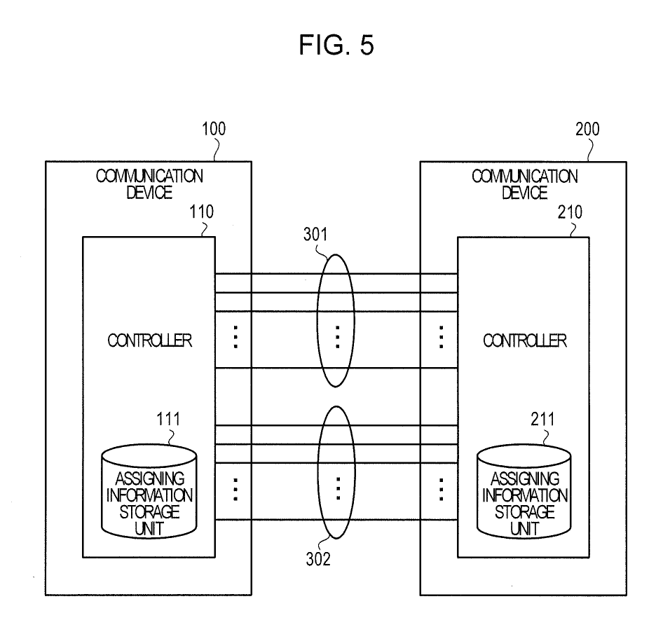

FIG. 5 is a diagram illustrating the communication devices according to the second embodiment. The communication devices 100 and 200 illustrated in FIG. 5 which are connected to each other through the serial links 301 and 302 communicate with each other through the serial links 301 and 302 so as to transmit and receive data. The communication device 100 includes a controller 110. The communication device 200 includes a controller 210. The controller 110 includes a assigning information storage unit 111. The controller 210 includes a assigning information storage unit 211.

The controller 110 assigns the correspondence relationships between physical lane numbers and logical lane numbers, the lanes being located between the communication device 100 and the communication device 200. Specifically, the controller 110 determines whether the lanes included in the serial links 301 and 302 are available. Subsequently, the controller 110 assigns logical lane numbers to available lanes in ascending order of the physical lane numbers or descending order of the physical lane numbers in accordance with results of the determination. The controller 110 stores the assigning information representing the correspondence relationships between the assigned physical lane numbers and the assigned logical lane numbers in the assigning information storage unit 111. Furthermore, the controller 110 executes a process of establishing the links of the serial links 301 and 302 in accordance with the logical lane numbers represented by the assigning information stored in the assigning information storage unit 111. In this way, the communication devices 100 and 200 communicate with each other through the serial links 301 and 302 so as to transmit and receive data. The controller 110 functions as a communication circuit.

The assigning information storage unit 111 stores the assigning information representing the correspondence relationships between the physical lane numbers and the logical lane numbers. In the second embodiment, the assigning information is represented by a shift number m which represents a difference between a certain physical lane number and a corresponding logical lane number.

The serial link 301 is used for data transmission from the communication device 100 to the communication device 200. The serial link 302 is used for data transmission from the communication device 200 to the communication device 100. Each of the serial links 301 and 302 includes n lanes which are synchronized with one another. Furthermore, physical lane numbers 0 to n−1 are assigned to the lanes included in each of the serial links 301 and 302.

The controller 210 has the same configuration as the controller 110, and therefore, a description thereof is omitted.

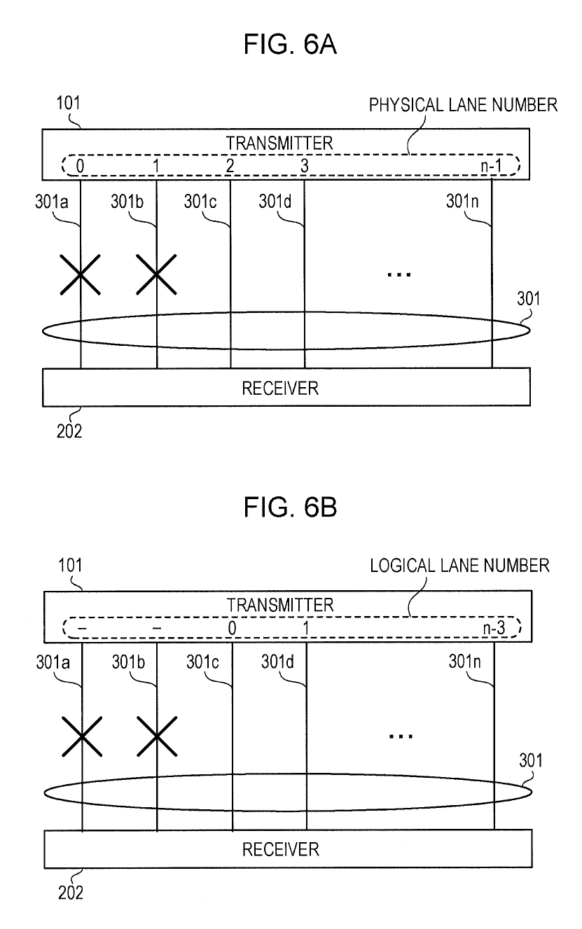

FIGS. 6A and 6B are diagrams illustrating a reconfiguration of lanes according to the second embodiment. FIG. 6A illustrates a case where failures have occurred in lanes having the physical lane numbers of 0 and 1 in the n lanes included in the serial link 301 which connects the transmitter 101 and the receiver 202 to each other according to the second embodiment. FIG. 6B illustrates a case where logical lane numbers are assigned to the n lanes included in the serial link 301 which connects the transmitter 101 and the receiver 202 to each other according to the second embodiment except for the failed lanes having the physical lane numbers of 0 and 1. Note that, the physical lane numbers are assigned in accordance with arrangement of lanes 301a to 301n irrespective of availability of the serial link 301.

The communication devices 100 and 200 of the second embodiment establish a link through the serial link 301 between the transmitter 101 of the communication device 100 and the receiver 202 of the communication device 200 as illustrated in FIGS. 6A and 6B.

As illustrated in FIG. 6A, it is assumed that the n lanes (16 lanes, for example) included in the serial link 301 are determined as the lanes 301a to 301n. Note that, in FIG. 6A, the lanes 301a and 301b which have the physical lane numbers of 0 and 1, respectively, are not available since failures have occurred in the lanes 301a and 301b.

In this case, the communication devices 100 and 200 determine whether the lanes 301a to 301n of the serial link 301 are available by transmitting the lane numbers to and receiving the lane numbers from the other. In this way, the communication devices 100 and 200 recognize that the lanes 301a and 301b are not available but the lane 301c is available.

First, the communication devices 100 and 200 perform reconfiguration of the serial link 301 using the available lanes among the lanes 301a to 301n. The communication devices 100 and 200 extract the available lanes by transmitting the lane numbers to and receiving the lane numbers from the other. Next, the communication devices 100 and 200 obtain a physical lane number of one of the lanes (the lane 301c in FIG. 6A, for example) which has the smallest physical lane number (2, for example) from results of the extraction of the available lanes. Subsequently, the communication devices 100 and 200 assign the obtained physical lane number to a shift number m included in the assigning information.

As illustrated in FIG. 6B, in the second embodiment, the physical lanes and the logical lanes of the serial link 301 correspond to each other in accordance with the shift number m included in the assigning information. Specifically, results obtained by subtracting the shift number m (2, for example) from the physical lane numbers of the available lanes are assigned as the logical lane numbers. For example, as illustrated in FIG. 6B, 0 is assigned as a logical lane number of the lane 301c having the physical lane number of 2 as illustrated in FIG. 6A. Furthermore, 1 is assigned as a logical lane number of the lane 301d having the physical lane number of 3. Similarly, n−3 is assigned as a logical lane number of the lane 301n having the physical lane number of n−1. Next, the communication devices 100 and 200 execute a process of establishing links of the lanes of the serial link 301 in accordance with the assigned logical lane numbers.

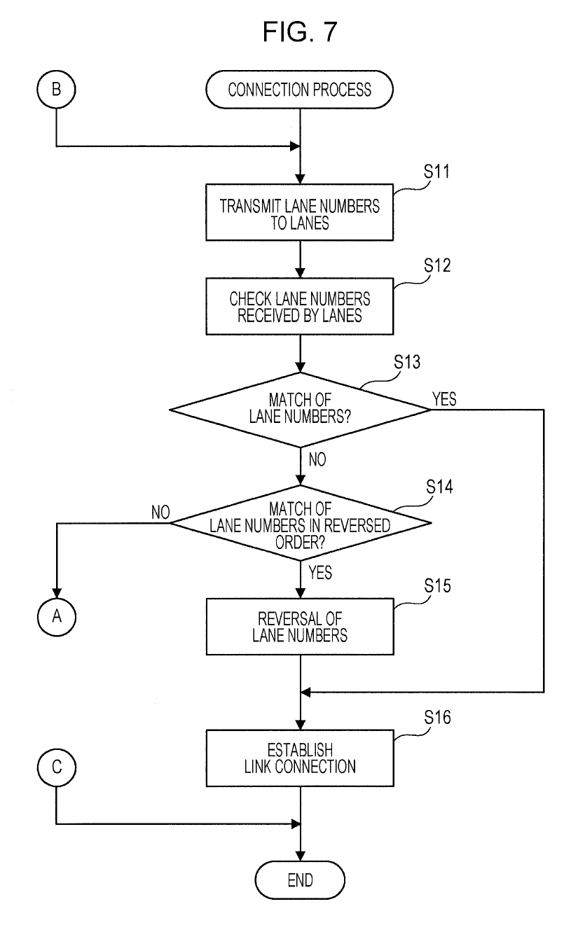

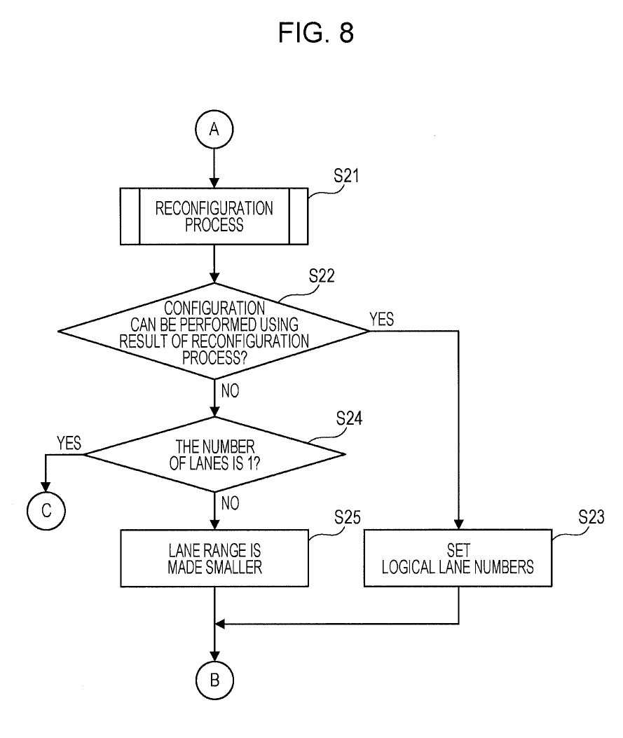

FIGS. 7 and 8 are flowcharts illustrating a connection process according to the second embodiment. In the connection process, lanes included in the serial links 301 and 302 which are used for communication between the communication devices 100 and 200 are assigned and links of the assigned lanes are established. Here, although a process executed by the controller 110 included in the communication device 100 when the link of the serial link 301 is established will be described, the controller 210 of the communication device 200 simultaneously executes a similar process. Hereinafter, the process illustrated in FIGS. 7 and 8 will be described in order of step numbers.

In step S11, the controller 110 transmits lane numbers of the lanes of the serial link 301 obtained at a certain time point. Note that, if logical lane numbers are assigned in step S21, the lanes obtained at the certain time point correspond to lanes having the logical lane numbers. When the logical lane numbers are not assigned, the lanes obtained at the certain time point correspond to lanes in an initial state of the connection process (that is, all the lanes of the serial link 301). Similarly, the communication device 200 transmits lane numbers of the lanes of the serial link 301 obtained at the certain time point.

In step S12, the controller 110 checks the lane numbers of the lanes of the serial link 301 supplied from the communication device 200. In step S11 and step S12, available lanes of the serial link 301 can be obtained.

In step S13, the controller 110 compares the lane numbers transmitted in step S11 and the lane numbers received in step S12 with each other and determines whether all the transmitted lane numbers and all the corresponding received lane numbers match each other. When the lane numbers match each other (that is, when the determination is affirmative in step S13), the process proceeds to step S16. On the other hand, when the lane numbers do not match each other (that is, when the determination is negative in step S13), the process proceeds to step S14.

In step S14, the controller 110 compares the lane numbers of the lanes transmitted in step S11 and the lane numbers received in step S12 with each other and determines whether all the transmitted lane numbers and all the corresponding received lane numbers match each other in reversed order. Note that the match in the reversed order means a case where the lane numbers on the communication device 100 side arranged in descending order and the lane numbers on the communication device 200 side arranged in ascending order match each other one by one. When the lane numbers match each other in reversed order (that is, when the determination is affirmative in step S14), the process proceeds to step S15. On the other hand, when the lane numbers do not match each other even in the reversed order (that is, when the determination is negative in step S14), the process proceeds to step S21 (in FIG. 8).

In step S15, the controller 110 assigns the lane numbers of the communication device 100 in reversed order. Note that, when the lane numbers of the communication device 100 are reversed, the communication device 200 does not perform reversal of the lane numbers of itself. Furthermore, when the lane numbers of the communication device 200 are reversed, the communication device 100 does not perform reversal of the lane numbers of itself. This is because the lane numbers are assigned in a reversal manner if the lane numbers of both of the communication devices 100 and 200 are reversed.

In step S16, the controller 110 establishes a connection of the link of the serial link 301 using the lane numbers obtained at the certain time point. Thereafter, the communication device 100 terminates the process.

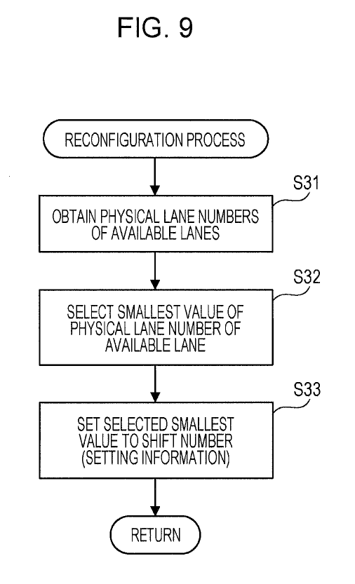

In step S21, the controller 110 executes a reconfiguration process for assigning logical lane numbers. In a first loop, the reconfiguration process is executed all the lanes of the serial link 301. In a second loop onwards, the reconfiguration process is performed on a number of lanes reduced in step S25. The reconfiguration process in the second embodiment will be described hereinafter in detail with reference to FIG. 9.

In step S22, the controller 110 determines whether the serial link 301 can be configured using a number of lanes reduced in step S25 in accordance with the logical lane numbers assign in the reconfiguration process in step S21. When the configuration is successfully performed (that is, when the determination is affirmative in step S22), the process proceeds to step S23. On the other hand, when the configuration is failed (that is, when the determination is negative in step S22), the process proceeds to step S24.

In step S23, the controller 110 assigns the logical lane numbers in accordance with the assigning information assign in the reconfiguration process performed in step S21 and continues the connection process. Thereafter, the process proceeds to step S11.

In step S24, the controller 110 determines whether the current number of lanes has been reduced to 1 since the number of lanes of the serial link 301 is reduced in step S25 in a loop of the connection process. When the current number of lanes is 1 (that is, when the determination is affirmative in step S24), the process is terminated. On the other hand, when the current lane number is 2 or more (that is, when the determination is negative in step S24), the process proceeds to step S25.

In step S25, the controller 110 reduces the number of lanes to be used among the lanes of the serial link 301 by one. Note that, although the controller 110 reduces the number of lanes by one except for a lane having the largest physical lane number, the present disclosure is not limited to this and the number of lanes may be reduced by one except for a lane having the smallest physical lane number. Thereafter, the process proceeds to step S11.

Note that, although each of the lanes in the serial links 301 and 302 is independently subjected to the determination in the connection process of the second embodiment, the present disclosure is not limited to this and the lanes of the serial links 301 and 302 may be collectively subjected to the determination so that the link is established.

FIG. 9 is a flowchart illustrating the reconfiguration process according to the second embodiment. In the reconfiguration process, assigning information representing the logical lane numbers of the lane of the serial link 301 used for the communication between the communication devices 100 and 200 is assigned. Here, although a process executed by the controller 110 included in the communication device 100 when the assigning information of the serial link 301 is assigned will be described, the controller 210 of the communication device 200 simultaneously executes a similar process. Hereinafter, the process illustrated in FIG. 9 will be described in order of step numbers.

In step S31, the controller 110 obtains physical lane numbers of the available lanes among the lanes of the serial link 301 in accordance with the results of the obtainment in step S11 and step S12.

In step S32, the controller 110 selects the smallest value in the physical lane numbers of the available lanes which are obtained in step S31.

In step S33, the controller 110 assigns the smallest value selected in step S32 as the shift number m included in the assigning information. Thereafter, the process returns to the connection process.

Note that, in the second embodiment, the loop is repeatedly executed while the number of lanes to be used is reduced in step S25 until the link is established in step S16. However, the present disclosure is not limited to this. After the available lanes are obtained in step S11 and step S12, the assigning information may be assigned in the reconfiguration process and the number of lanes to be used may be determined in accordance with the assigning information. Then the logical lane numbers may be assigned in accordance with the assigning information and the determined number of lanes and the serial links 301 and 302 may be assigned in accordance with the assigned logical lane numbers.

As described above, according to the second embodiment, when a lane included in a serial link is unavailable due to a failure, for example, the serial link can be established using available lanes irrespective of a position of the unavailable lane.

Furthermore, when the serial link is employed in a long-distance line and a failure rate of the lanes is not reduced, the serial link can be established while reduction of the communication capacity is suppressed by making effective use of the available lanes.

Furthermore, since the correspondence relationships between the physical lane numbers and the logical lane numbers are identified in accordance with the assigning information so that the logical lane numbers are assigned to the plurality of serial links and data transmission and data reception are performed while the lanes are synchronized with one another, this embodiment is applicable to a multilane configuration.

### Third Embodiment

Next, the third embodiment will be described. The description is mainly made in components different from the second embodiment and reference numerals the same as those of the second embodiment are assigned to components the same as those of the second embodiment. Therefore, descriptions of the same components are omitted.

In the third embodiment, a serial link is established by assigning logical lane numbers to available lanes in turn.

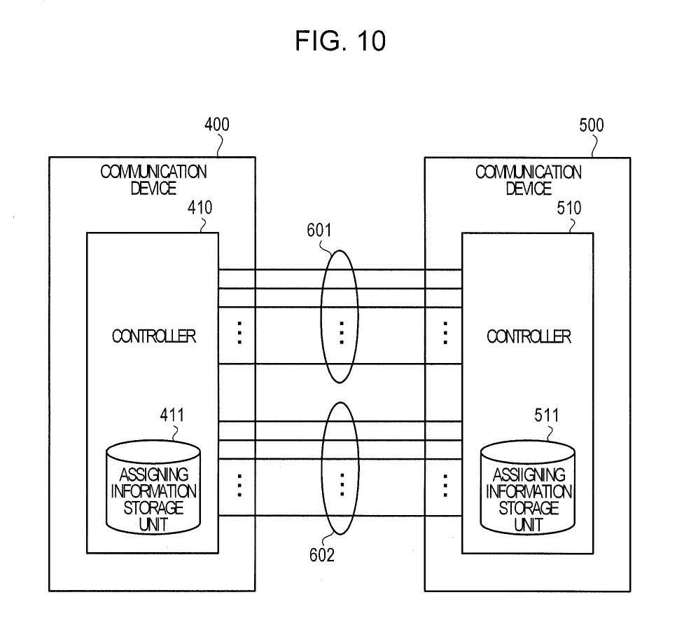

FIG. 10 is a diagram illustrating communication devices according to the third embodiment. Communication devices 400 and 500 illustrated in FIG. 10 which are connected to each other through serial links 601 and 602 communicate with each other through the serial links 601 and 602 so as to transmit and receive data. The communication device 400 includes a controller 410. The communication device 500 includes a controller 510. The controller 410 includes a assigning information storage unit 411. The controller 510 includes a assigning information storage unit 511.

The controller 410 assigns the correspondence relationships of logical lanes between the communication device 400 and the communication device 500 which is a counterpart of the communication device 400. Specifically, the controller 410 determines whether lanes included in the serial links 601 and 602 are available. Subsequently, the controller 410 ignores unavailable lanes in accordance with results of the determination and assigns logical lane numbers to available lanes. The controller 410 stores assigning information representing the correspondence relationships between the assigned physical lane numbers and the assigned logical lane numbers in the assigning information storage unit 411. Furthermore, the controller 410 executes a process of establishing the links of the serial links 601 and 602 in accordance with the logical lane numbers represented by the assigning information stored in the assigning information storage unit 411. In this way, the communication devices 400 and 500 communicate with each other through the serial links 601 and 602 so as to transmit and receive data. The controller 410 functions as a communication circuit.

The assigning information storage unit 411 stores the assigning information representing the correspondence relationships between the physical lane numbers and the logical lane numbers. In the third embodiment, in the assigning information, the unavailable lanes are ignored and the logical lane numbers are assigned in ascending order to the physical lane numbers which are sorted in ascending order (or in descending order).

The serial link 601 is used for data transmission from the communication device 400 to the communication device 500. The serial link 602 is used for data transmission from the communication device 500 to the communication device 400. Each of the serial links 601 and 602 includes n lanes which are synchronized with one another. Furthermore, physical lane numbers 0 to n−1 are assigned to the lanes included in each of the serial links 601 and 602.

The controller 510 has the same configuration as the controller 410, and therefore, a description thereof is omitted.

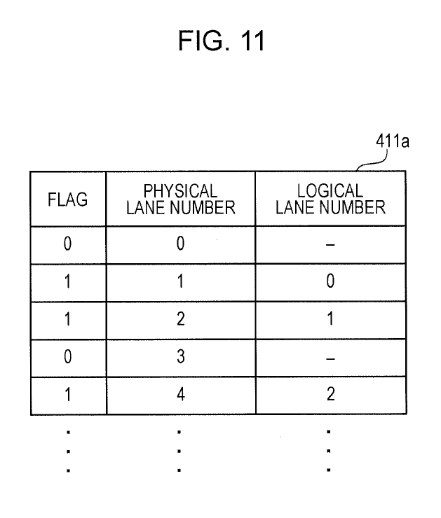

FIG. 11 is a diagram illustrating a assigning table 411a according to the third embodiment. The assigning table 411a illustrated in FIG. 11 is stored in the assigning information storage unit 411 included in the communication device 400. The assigning table 411a stores the assigning information representing the correspondence relationships between the physical lane numbers and the logical lane numbers of the serial link 601. Although assigning information is similarly assigned to the serial link 602, a description thereof is omitted since the assigning information is configured the same as that of in the assigning table 411a. Moreover, although assigning tables which store the assigning information of the serial links 601 and 602 are stored in the assigning information storage unit 511 of the communication device 500, descriptions thereof are omitted since the assigning tables are configured the same as those of the assigning table 411a in the assigning information storage unit 411.

The assigning table 411a includes items “flag”, “physical lane number”, and “logical lane number”. In the assigning table 411a, information items of the items which are horizontally arranged are associated with one another as assigning information.

The item “flag” represents whether the lanes are available. When a lane is available, 1 is assigned, for example. On the other hand, when a lane is not available, 0 is assigned.

The item “physical lane number” represents physical lane numbers of the lanes of the serial link 601. The lanes of the serial link 601 may be identified by the physical lane numbers.

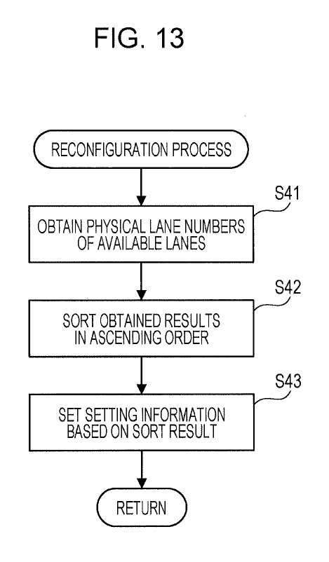

The item “logical lane number” represents logical lane numbers assigned by the controller 410 to physical lane numbers of available lanes in a reconfiguration process which will be described hereinafter with reference to FIG. 13.

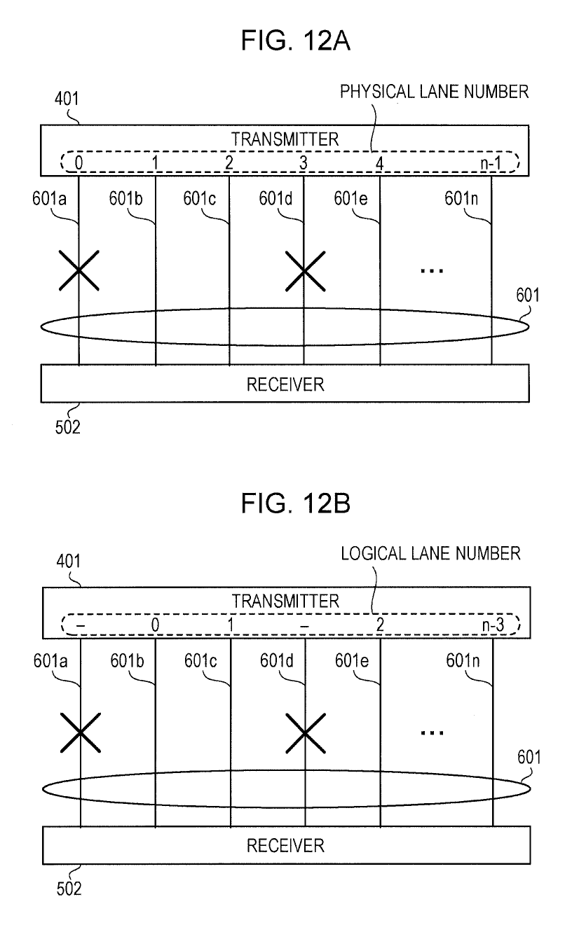

FIGS. 12A and 12B are diagrams illustrating the reconfiguration of lanes according to the third embodiment. FIG. 12A illustrates a case where failures have occurred in lanes having the physical lane numbers of 0 and 3 in the n lanes included in the serial link 601 which connects the transmitter 401 and the receiver 502 to each other according to the third embodiment. FIG. 12B illustrates a case where logical lane numbers are assigned to the n lanes included in the serial link 601 which connects the transmitter 401 and the receiver 502 to each other according to the third embodiment except for the failed lanes having the physical lane numbers of 0 and 3. Here, the physical lane numbers are assigned in accordance with arrangement of lanes 601a to 601n irrespective of availability of the serial link 601.

The communication devices 400 and 500 of the third embodiment establish a link of the serial link 601 between the transmitter 401 of the communication device 400 and the receiver 502 of the communication device 500 as illustrated in FIGS. 12A and 12B.

As illustrated in FIG. 12A, it is assumed that the n lanes (16 lanes, for example) included in the serial link 601 are determined as lanes 601a to 601n. Note that, in FIG. 12A, the lanes 601a and 601d which have the physical lane numbers of 0 and 3, respectively, are not available since failures have occurred in the lanes 601a and 601d.

In this case, the communication devices 400 and 500 determine whether the lanes 601a to 601n of the serial link 601 are available by transmitting the lane numbers to and receiving the lane numbers from the other. In this way, the communication devices 400 and 500 recognize that the lanes 601a and 601d are not available but the lane 601c is available.

First, the communication devices 400 and 500 perform reconfiguration of the serial link 601 using the available lanes included in the lanes 601a to 601n. The communication devices 400 and 500 extract the available lanes by transmitting the lane numbers to and receiving the lane numbers from the other. Next, the communication devices 400 and 500 assign logical lane numbers in ascending order to the available lanes arranged in ascending order of the physical lane numbers so as to generate assigning information representing a result of the assigning.

As illustrated in FIG. 12B, in the third embodiment, the correspondence relationships between the physical lanes numbers and the logical lane numbers of the serial link 601 are represented by the assigning information. For example, to the lane 601c having the physical lane number of 2 as illustrated in FIG. 12A, 1 is assigned as a logical lane number by ignoring the unavailable lane 601a having a physical lane number smaller than that of the lane 601c as illustrated in FIG. 12B. Furthermore, to the lane 601e having the physical lane number of 4, 2 is assigned as a logical lane number by ignoring the unavailable lanes 601a and 601d which have physical lane numbers smaller than that of the lane 601e. Similarly, n−3 is assigned as the logical lane number of the lane 601n having a physical lane number of n−1 if another unavailable lane does not exist. Next, the communication devices 400 and 500 execute a process of establishing links of the lanes of the serial link 601 in accordance with the assigned logical lane numbers.

Note that, in the third embodiment, the logical lane numbers are assigned in ascending order to the lanes arranged in ascending order. However, the present disclosure is not limited to this and the logical lane numbers may be assigned in ascending order to the lanes arranged in descending order.

FIG. 13 is a flowchart illustrating the reconfiguration process according to the third embodiment. In the reconfiguration process, the assigning information representing the logical lane numbers of the lane of the serial link 601 used for the communication between the communication devices 400 and 500 is assigned. Here, although a process executed by the controller 410 included in the communication device 400 when the assigning information of the serial link 601 is assigned will be described, the controller 510 of the communication device 500 simultaneously executes a similar process. Hereinafter, the process illustrated in FIG. 13 will be described in order of step numbers.

In step S41, the controller 410 obtains the physical lane numbers of the available lanes among the lanes of the serial link 601 in accordance with the results of the obtainment in step S11 and 12. Furthermore, the controller 410 assigns results of a determination as to whether the lanes are available in the item “flag” of the assigning information stored in the assigning information storage unit 411.

In step S42, the controller 410 sorts in ascending order the physical lane numbers of the available lanes which are obtained in step S41.

In step S43, the controller 410 assigns the logical lane numbers in ascending order to the lanes having the physical lane numbers arranged in ascending order in accordance with a result of the sorting performed in step S42 and determines the assigned logical lane numbers as the assigning information. In this way, the unavailable lanes are ignored and the logical lane numbers are assigned to the available lanes in the assigning information. Thereafter, the process returns to a connection process.

Note that, in the connection process of the third embodiment which is similar to that of the second embodiment, a loop is repeatedly executed while the number of lanes to be used is reduced in step S25 until the link is established in step S16. However, the present disclosure is not limited to this. After the available lanes are obtained in step S11 and step S12, the assigning information may be assigned in the reconfiguration process, the logical lane numbers may be assigned in accordance with the assigning information, and the serial links 601 and 602 may be assigned using the assigned logical lane numbers.

As described above, according to the third embodiment, in addition to the effects of the second embodiment, since a serial link can be established even when available lanes are not successively arranged, reduction of the number of lanes to be used can be suppressed. Accordingly, deterioration of usage efficiency of available lanes can be suppressed.

The communication devices, the communication circuits, and the communication methods in the present disclosure have been described on the basis of the embodiments illustrated in the drawings hereinabove. The configurations of the components may be replaced by arbitrary configurations having the same functions. Furthermore, other arbitrary components and steps may be added to the technique in the present disclosure. In addition, the technique of the present disclosure may be obtained as a combination of two or more arbitrary configurations of the foregoing embodiments.

In all embodiments, the controller may include at least one of IC circuit, FPGA (Field Programmable Gate Array) and processor. Additionally, the assigning information storage units 111, 211, 411 and 511 may include memory.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A communication device which performs communication using a transmission path including a plurality of communication lines, the communication device comprising:
a controller configured to determine whether the communication lines are available, assign logical communication line numbers to communication lines selected from the communication lines, which are determined to be available in accordance with results of the determination in ascending order or descending order of the communication line numbers, and perform a process of establishing a link of the transmission path in accordance with the assigned logical communication line numbers.

2. The communication device according to claim 1, wherein the controller
assigns the logical communication line numbers to the communication lines determined to be available in ascending order of the communication line numbers in accordance with the results of the determination, and
performs the process of establishing the link in accordance with the assigned logical communication line numbers.

3. The communication device according to claim 1, wherein the controller
includes an assigning information storage unit configured to store assigning information representing a correspondence relationship between the communication line numbers and the logical communication line numbers,
assigns the correspondence relationships between the communication device and a counterpart device and causes the assigning information storage unit to store the assigning information representing the correspondence relationships, and
establishes the link in accordance with the assigned logical communication line numbers represented by the assigning information.

4. A communication circuit which performs communication using a transmission path including a plurality of communication lines, the communication circuit comprising:
a controller configured to determine whether the communication lines are available, assign logical communication line numbers to communication lines selected from the communication lines, which are determined to be available in accordance with results of the determination in ascending order or descending order of the communication line numbers, and perform a process of establishing a link of the transmission path in accordance with the assigned logical communication line numbers.

5. A method for performing communication using a transmission path including a plurality of communication lines, the communication method comprising:
determining whether the communication lines are available using a processor,
assigning logical communication line numbers to communication lines selected from the communication lines, which are determined to be available in accordance with results of the determination in ascending order or descending order of the communication line numbers using the processor, and
establishing a link of the transmission path in accordance with the assigned logical communication line numbers using the processor.
